(19) United States
(12) Patent Application Publication
(10) Pub. No.: US 2024/0330526 A1
(43) Pub. Date: Oct. 3, 2024

(54) COMPUTER-IMPLEMENTED METHOD AND APPARATUS TO DESIGN AND CONSTRUCT ON-PREMISES WATER TREATMENT SYSTEMS

(71) Applicant: LEAF HOME WATER SOLUTIONS, LLC, Hudson, OH (US)

(72) Inventors: Thomas Victor CZERNY, Streetsboro, OH (US); Michael GORI, Hudson, OH (US); Timothy Howard DUNPHY, Hudson, OH (US); James Waco STORY, East Palatka, FL (US); Christopher Adam CROWELL, Uniontown, OH (US)

(21) Appl. No.: 18/127,762

(22) Filed: Mar. 29, 2023

(51) Int. Cl. G06F 30/18; C02F 1/00

(52) U.S. Cl. CPC G06F 30/18; C02F 1/008; C02F 2209/006; C02F 2209/008; C02F 2209/03; C02F 2209/055; C02F 2209/06; C02F 2209/29

(57) ABSTRACT

Computer-aided design of water treatment systems assesses very large numbers of variables and conditions to facilitate water treatment system recommendations. In an embodiment, field engineers or sales representatives at virtually any level of experience can take water samples and gather site data on a customer's site and input the sample data and the site data to a computing system, which may be a standalone portable device or may be a portable device connected via a network or the cloud to a central computing system.

### FIELD OF THE INVENTION

The present invention relates to water treatment systems. More particularly, the present invention relates to computer-implemented rapid customized design of water treatment systems to accommodate a wide range of requirements and water conditions. In one aspect, the present invention relates to installation of water treatment systems with such customized designs.

### BACKGROUND

Water quality can vary from household to household due to several factors. Some of the most common causes of variation in water quality include:
Water source: Water source can have a significant impact on water quality. Municipal water systems, private wells, and surface water sources such as lakes, rivers, and streams can all have different levels of contaminants and minerals.
Plumbing age and condition: The age and condition of the pipes that carry water into a premises can affect water quality. Older pipes may be made of materials that leech contaminants into the water. Corroded pipes can introduce metals like lead and copper.
Geographic location: Premises location also can have an impact on water quality. For example, agricultural areas may have higher levels of pesticides and fertilizers in the water. Other areas may have water that is harder or softer, with areas with high mineral content in the soil having higher levels of certain minerals like calcium or iron.
Environmental factors: Environmental factors such as flooding, drought, and temperature changes can also impact water quality by changing the levels of contaminants and minerals in the water. Additionally, natural disasters like hurricanes and earthquakes can damage water treatment facilities and lead to temporary changes in water quality. Private well homeowners are responsible for treating their own water regardless of what contaminants may be in the water. With municipal water sources, it may be presumed that the water is safe when it reaches a premises. However, municipal water systems often use some form of chlorine, chloramine, or chlorine dioxide to treat the water. Chlorine imparts a taste to the water that many would a desire to remove before consuming the water.

Several studies have indicated that over seven million people suffer from water contamination diseases (water borne diseases) every year across the U.S. In addition, the Centers for Disease Control (CDC) has estimated that water borne diseases add over $3.3 billion in costs each year to the U.S. healthcare system. These statistics demonstrate the growing need for residential water treatment systems.

In view of the foregoing, water treatment products and systems are becoming more and more widespread. For example, The U.S. water purification market is projected to grow to $9.1 billion by 2029, up from $5.85 billion in 2021.

### DESCRIPTION OF THE CONVENTIONAL ART

Water treatment systems for residences and/or commercial buildings can be complex, entailing consideration of not only local water sources and their water qualities but also system size and usage, as well as existing valving and/or piping. The number of variables involved in determining water quality and ascertaining appropriate water treatment is daunting. Moreover, different water treatment equipment with different functions may operate under different conditions, making it challenging for field technicians and/or sales engineers to determine on their own whether appropriate combinations of such equipment, to treat a wide range of water conditions, is even possible. Even the number of conditions can represent a substantial challenge. The overall number of permutations and combinations of variables and conditions is virtually limitless.

Still further, some water sources may be in such hazardous condition that localized water treatment equipment would be insufficient, and in some cases, even unable to address one or more of the hazards. In such circumstances, a more centralized approach to water treatment, for example, at the water source itself, may be required.

In ascertaining the availability of appropriate water treatment solutions for residences and/or commercial buildings, it is necessary to account for this large number of variables and conditions. It would be desirable to facilitate determination of whether such water treatment solutions are possible and, if they are, what solution(s) may be provided.

### SUMMARY OF THE INVENTION

One aspect of the invention provides a practical application of computer technology to address the virtually limitless number of permutations and combinations of variables and conditions, in a way that would not be practicable or possible through human-based assessment, with more accurate recommendations. The speed and accuracy of the recommendations enables even junior (relatively inexperienced) field technicians or sales representatives to provide prompt, coherent, accurate water treatment recommendations. The overall efficiency and accuracy in turn facilitates design of appropriate water treatment systems, thereby advancing the timing of installation of such systems.

In an embodiment, a user such as a field technician or sales representative inputs water-related information, including water testing results and data relating to the facility needing the water treatment equipment, to a portable device. In an embodiment, the portable device communicates the information to a central computing system which identifies possible water treatment system solutions and communicates them back to the portable device. In an embodiment, the portable device itself contains the necessary information to respond to the inputs and identify the possible water treatment system solutions. In an embodiment, the user inputs the water testing results to the portable device by connecting testing equipment directly to the portable device, thereby reducing the chances for input errors.

The following detailed description includes non-exhaustive lists of variables and conditions which may be relevant to water treatment recommendations. Ordinarily skilled artisans will recognize that, depending on the circumstances, other variables and conditions may come into play.

### BRIEF DESCRIPTION OF DRAWINGS

The foregoing and other aspects and features according to embodiments of the present invention now will be described in detail with reference to the accompanying drawings, in which:

FIG. 1 is a flowchart providing a broad outline of the overall method according to an embodiment.

FIG. 2 is a flowchart addressing exemplary criteria for identification of suitable water treatment apparatus according to an embodiment.

FIG. 3 is a flowchart addressing exemplary criteria for identification of suitable water treatment apparatus according to an embodiment.

FIGS. 4A-4C are flowcharts addressing exemplary criteria for identification of suitable water treatment apparatus according to an embodiment.

FIGS. 5A-5D are flowcharts addressing exemplary criteria for identification of suitable water treatment apparatus according to an embodiment.

FIG. 6 is a diagram of a premises in which water treatment systems according to embodiments of the invention may be employed.

FIG. 7 is a high level diagram of a processing system to implement aspects of the invention according to an embodiment.

### DETAILED DESCRIPTION

Design of water treatment systems entails evaluation of a large number of parameters, some relating to characteristics of the water being treated, some relating to water supply and/or source, some relating to treatment apparatus to be installed, some relating to pre-existing on-premises equipment, some relating to installation itself.

The following is a non-exhaustive list of parameters to take into account during design and/or installation. Ordinarily skilled artisans will recognize many, if not all of these parameters, and also will be aware of others. In some aspects, these parameters will have ranges, yielding a very large number of variables which must be addressed. In some aspects, these parameters will signify conditions which, taken together with the variables, yield a virtually limitless number of combinations which are daunting to address, and in a number of instances, impractical to address within a reasonable time. Small changes in values of some of these parameters can yield very different water treatment approaches and/or solutions.

Depending on the embodiment, the non-exhaustive list of parameters may include any or all of the following:
Water source-city, well, or other;
Water pressure from the source;
Water characteristics, including but not limited to:
   pH
   Odor
   Taste
   Color (including cloudiness);
   Flavor
   Hardness
   Salinity
Metal content, including but not limited to:
   Iron
   Copper
   Lead
   Manganese
Other water attributes, including but not limited to:
   Total dissolved solids (TDS)
   Sediment
   Rust
   Bacteria
Other water content, including but not limited to:
   Nitrates
   Nitrites
   Chlorine (including one or more of free chlorine, combined chlorine, and total chlorine)
   Hydrogen sulfide (H₂S)
Water treatment apparatus, including but not limited to
   Water softener
   Water conditioner
   Ultraviolet (UV) treatment
   Reverse osmosis (RO) treatment
   Number of connections
Characteristics of facility in which water treatment apparatus is to be installed, including but not limited to:
   Installation location and/or level
   Number of people at the facility
   Number of water outlets

Ordinarily skilled artisans will appreciate that a number of the above-mentioned parameters, including but not necessarily limited to water characteristics, metal content, other water attributes, other water content, and/or facility characteristics have relevant ranges of interest. Merely by way of nonlimiting example, water treatment apparatus may be able to handle metal content up to a certain amount, which may be different for different metals. The same range-limiting circumstances may be true for pH, rust, bacteria, H₂S, and other attributes. Certain water pressure ranges may be applicable. Depending on the water treatment apparatus and/or system under consideration, some of the ranges of interest for a given parameter may be the same; they may overlap; or they may be mutually exclusive.

In some instances, characteristics of the water to be treated are such that treatment of the water supply itself, rather than treatment of the water at the location of use, is required or highly recommended. Depending on the embodiment, one or more of the following characteristics may point to the desirability of treating the water supply:
Hardness outside of a range of treatment ability of the treatment apparatus;
Metal content, including but not limited to iron and manganese, outside of a range of treatment ability of the treatment apparatus;
Excessive TDS;
Excessive nitrates;
Excessive pH

In one aspect, the foregoing list may be sorted into the following groups:
Water hardness;
Sediment
Odors
Color or cloudiness
Taste
Metal
Chemical contamination
Bacterial contamination
Rust

Ordinarily skilled artisans will appreciate that there will be some overlap in some of the just listed categories. By way of nonlimiting example, odors may come from presence of H₂S (rotten eggs), or from some form of chlorine. Despite the existence of such overlap, multiple types of water treatment apparatus may be involved in addressing different odor issues. For example, a filtration apparatus may be more effective at removing rotten egg smell, while a water conditioning or other softening apparatus may be more effective at removing other chemical smells, such as chlorine contamination.

Some filtration apparatus also may be more effective at removing particulates than are other water treatment apparatus. Water softening apparatus or other water conditioning apparatus may be more effective at addressing water hardness, chemical contamination, and taste than at removing various types of particulates.

In some cases, existing equipment on site, such as pipes, hot water heaters or even existing water treatment equipment, may be responsible for some of the water characteristics pointing to a need for treatment.

In some embodiments, the above list of criteria may be grouped according to the type of equipment to be employed. For example, some water softening equipment may address issues of water hardness, taste, and/or chemical contamination. Certain water conditioning equipment may address the same issues. Some filtration equipment may not address water hardness or chemical contamination, but may address issues such as sediment, odor (particularly H₂S), color or cloudiness, taste, metals such as lead, and/or rusty water. UV equipment may address issues of bacterial contamination. Reverse osmosis equipment may address all of the foregoing issues except for bacterial contamination.

Some water treatment equipment may be intended to work throughout an entire residence or other building, and so may be installed at a point of entry of the water source to that structure. Other water treatment equipment may be intended to work at a point of exit of water within a residence or other building, for example, a faucet, water dispenser, or refrigeration unit (an icemaker or water dispenser contained within the refrigeration unit).

Some types of water treatment equipment that may address similar or identical issues may operate under different criteria. That is, some water treatment equipment addressing similar or identical issues may operate under one or more sets of criteria, while other water treatment equipment addressing the same issues may operate under criteria that do not overlap entirely. Where the criteria do not overlap, one or the other of the equipment may be unsuitable for the particular purpose.

Ordinarily skilled artisans will appreciate that some water treatment equipment is not suitable for certain on-premises conditions. In such circumstances, addressing water condition issues at the premises may necessitate treatment at the water source itself rather than on the premises. In other circumstances, water condition issues may be the result of condition of on-premises piping, water heating apparatus, and the like. In these other circumstances, repairing or replacing the piping and/or water heating apparatus may be the appropriate response.

Ordinarily skilled artisans also will appreciate that, for example, if the water source is a well and the well is sufficiently contaminated, perhaps because of groundwater contamination, some other solution may be necessary, such as redigging of the well, or more general treatment of the groundwater.

From the foregoing listing of water treatment issues and approaches, ordinarily skilled artisans will appreciate that there is an almost limitless set of permutations and combinations of water conditions and water treatment equipment which must be addressed in order to identify suitable water treatment equipment for a given premises, or indeed to determine whether on-premises treatment is even possible. Different permutations and combinations of water conditions may have to be considered for different types of water treatment equipment.

Depending on the embodiment, the number of people occupying a premises, and/or a number of water outlets on a premises may determine required capacity and/or throughput of a particular water treatment apparatus, or whether such apparatus is even available for the number of people and/or water outlets on the premises. In some cases, multiple apparatus may be necessary to handle different portions of the premises. For example, in an apartment building a single water treatment apparatus for the entire building may not be possible. An apparatus and/or system for each floor, or a portion of each floor, may be necessary. Occupancy and usage contribute yet further to the number of permutations and combinations

As will be discussed in greater detail herein, aspects of the present invention facilitate and, in some cases, improve the design of water treatment systems by accommodating the various permutations and combinations and applying physical and water-related data for a particular premises to devise recommendations for possible water treatment systems for the premises. Aspects of the invention take advantage of computer processing power to run algorithms necessary to devise the recommendations. The algorithms provide rapid and accurate assessments of existing conditions at a premises, to enable prompt, straightforward, and accurate recommendations for water treatment systems. Aspects of the invention thus provide a practical application of computing equipment to design the water treatment systems by enabling more efficient and more accurate design recommendations. With prompt and efficient design, installation timing for the designed water treatment systems can be accelerated.

From the foregoing list of parameters and from their assessment in the flow charts that follow, ordinarily skilled artisans will appreciate the virtual impossibility of any field technician and/or sales engineer, however experienced, to devise a coherent recommendation that takes into account all of the possible permutations and combinations. Computer implementation, then, as mentioned above and discussed in greater detail below, will be indispensable to achieve acceptable designs. Aspects of the present invention, then, represent a practical application of computer technology to achieve designs which individuals cannot.

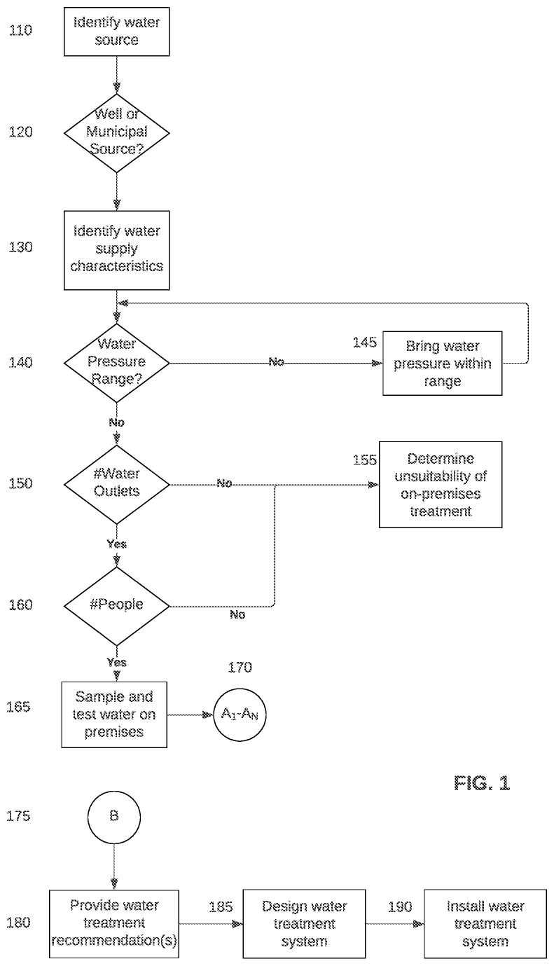

FIG. 1 is a flowchart providing a broad outline of identification of suitable water treatment apparatus and/or systems according to an embodiment. In embodiments, this assessment is done at the premises. In FIG. 1, at 110 the water source may be identified. At 120, in an embodiment it may be determined whether the water source is a well or a municipal source. Ordinarily skilled artisans will appreciate that there may be other water sources as well. Well water and municipal water are known to have different characteristics that can point to different treatment. While the different treatments may not be shown specifically in the Figures, ordinarily skilled artisans will appreciate that there may indeed be different treatments, depending on water characteristics.

At 130, water supply characteristics may be identified, and at 140, a water pressure range may be identified. In an embodiment, this may be a preliminary assessment, subject to further checking for the different types of water treatment apparatus that may be available. If the water pressure is outside of an acceptable range, at 145, the recommendation may include an adjustment to the water pressure to bring it within range. Depending on the embodiment, and/or on the water treatment apparatus under consideration, by way of example, water pressure may be between about 30 or 40 PSI and about 100 or 125 PSI. (In the present discussion, “about” means within plus or minus 10 percent of the indicated value.)

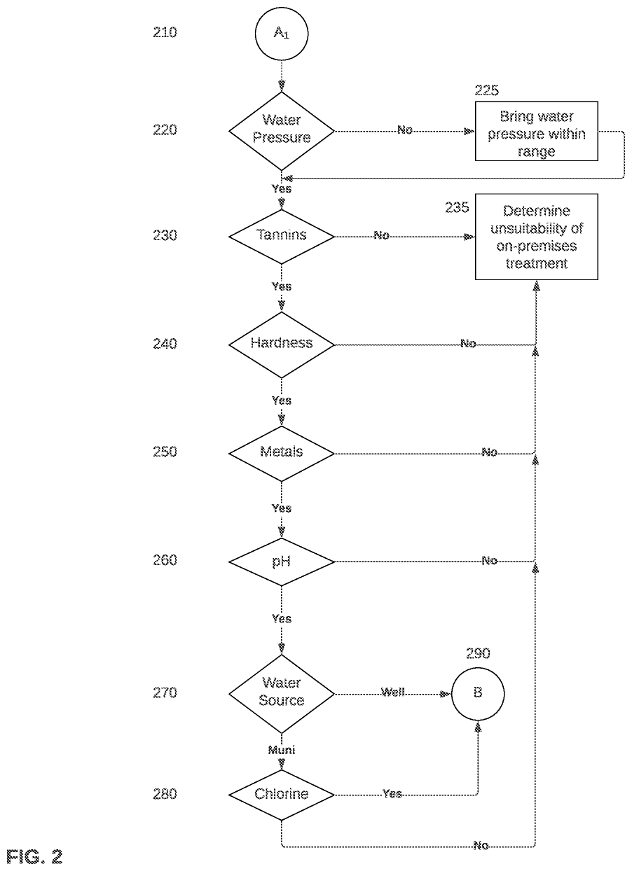

If the water pressure is within an acceptable range, then at 150, a number of outlets for water requiring treatment (e.g. sinks, showers, bathtubs, hot tubs, kitchen faucets, drinking faucets, icemakers, water dispensers, and the like) may be identified. At 160, a number of people that would be using the premises is identified. If there are too many water outlets and/or too many people, at 155 a determination may be made that on-premises treatment are unsuitable. It should be noted that, depending on the embodiment, these water outlet/people determinations could be carried out at any point in FIG. 1, or in one or more of FIGS. 2, 3, 4A-4C, and 5A-5D, as different water treatment systems may have different capacities. The water outlet/people determinations in FIG. 1 could be general, and the same determinations in FIGS. 2, 3, 4A-4C, and 5A-5D could be specific to the particular water treatment under consideration.

In an embodiment, where there are acceptable numbers of water outlets and people, there may be different recommendations for models of particular types of equipment, as discussed below with respect to FIGS. 2, 3, 4A-4C, and 5A-5D. Consequently, if conditions are suitable, for example, for a recommendation of a UV treatment apparatus, and/or an RO apparatus, and/or a water filtration apparatus, and/or a water conditioning apparatus, the size or type of apparatus (or, looking at this another way, system capacity) may vary according to the number of outlets and people in combination.

If the water outlet/people determination is satisfactory, then at 165 on-premises water sampling and testing is carried out. At this point, responsive to results of the test, at 170 flow branches to one or more of the possible treatment apparatus selections to see if the water quality merits one or more of these selections. These branches are discussed in greater detail with respect to FIGS. 2, 3, 4A-4C, and 5A-5D. In any of these branches, it may be determined that there is no suitable on-premises treatment for the water condition, in which case the flow ends at that point. In some embodiments, at least one, and in some instances more than one of the treatment possibilities may be indicated. That is, any or all of the treatment apparatus discussed in more detail below with respect to FIGS. 2, 3, 4A-4C, and 5A-5D may form part of an overall water treatment system for the premises.

It should be noted that each of the flowcharts in FIGS. 2, 3, 4A-4C, and 5A-5D show an entry point from the flowchart of FIG. 1, and a return point to the flowchart of FIG. 1. However, ordinarily skilled artisans will appreciate that water treatment assessments may be carried out serially, in any desired order, starting with the entry point from the flowchart of FIG. 1, and ending with the return point to the flowchart of FIG. 1. Depending on the embodiment, the respective assessments in each of FIGS. 2, 3, 4A-4C, and 5A-5D may be carried out in any order.

At 175, assuming there are one or more appropriate recommendations, flow resumes. At 180, a water treatment recommendation or recommendations may be provided. At 185, a design for a recommended water treatment system may be completed, and at 190, the designed system may be installed. The designed system may employ one or more of the apparatus discussed above (by way of non-limiting example, water softener, water conditioner, RO apparatus, or UV apparatus, among others). Depending on the embodiment, these apparatus may be supplemented by other apparatus, such as a taste and/or odor treatment apparatus.

At 195, electrical and/or mechanical components of the installed water treatment system may be configured. In an embodiment, configuration may include specific valve setting instructions to be programmed in order to configure the designed system at installation time, depending on the conditions of the application for which the water treatment system has been designed. As a nonlimiting example, regeneration cycle timing, and specific timing of each step within the regeneration (brine draw, backwash, rinse and refill timing) may need to be programmed as part of the configuration. In an embodiment, programing valve head controls in various parts of the system may be necessary in order to adjust the system's electrical and mechanical configuration depending on the conditions of the application for which the water treatment system has been designed.

In one aspect, FIG. 2 is a flowchart depicting a non-limiting exemplary path to identification of a suitable UV treatment apparatus according to an embodiment. In FIG. 2, at 210 the flow begins. In an embodiment, at 220, water pressure is assessed. Water pressure also is assessed in the flowchart of FIG. 1. However, depending on the embodiment, it is possible that water pressure may be in a suitable range for one type of treatment apparatus, but not for another. The water pressure assessment in FIG. 1 is a preliminary determination of whether the pressure is in a range that would be acceptable for at least one type of treatment apparatus. The ranges may be different for different types of water treatment apparatus. In an embodiment, the range may be from 30 to 125 pounds per square inch (PSI). Ordinarily skilled artisans will appreciate that the upper limit may be higher or lower (in a non-limiting example, 100 PSI), and that the lower limit may be higher or lower (in another non-limiting example, 40 PSI). If the water pressure assessment at 220 is unfavorable, a recommendation may be made to bring the water pressure within an acceptable range. Flow then proceeds to 230, at which tannin levels may be assessed. In some embodiments, some amount of tannins may be acceptable, but in other embodiments, there cannot be tannins present. If tannin levels are within a range that is acceptable for the apparatus to be proposed, then at 240 water hardness may be assessed. Depending on the embodiment, and on the water treatment apparatus in question, water hardness may have different upper limits. In some embodiments, the upper limit may be 75 grains per gallon (gpg). In some embodiments, the upper limit may be lower, for example, 72 gpg, or 70 gpg, or 60 gpg, or or 59 gpg, even below 10 gpg, for example, 7 gpg. Ordinarily skilled artisans will appreciate that different types of water treatment apparatus will accommodate and/or treat different levels of water hardness. Ordinarily skilled artisans will appreciate that different types of equipment, from the same or different manufacturers, may permit different upper limits of hardness. The numbers provided here are intended to be exemplary and not all-inclusive.

If water hardness is within a range that is acceptable for the apparatus, then at 250 an assessment for presence of one or more metals may be carried out. Metals that may be tested for may include, but are not limited to copper, lead, iron, and manganese. Ordinarily skilled artisans will appreciate that in different environments, different metals may be present in a water supply, and so may need to be tested for.

Depending on the embodiment, and on the water treatment apparatus in question, metal amounts may have different upper limits. In some non-limiting embodiments, copper amount may have an upper limit of 0.1 ppm. Depending on the embodiment, and on the water treatment apparatus in question, copper amount may have a higher or a lower upper limit. In some non-limiting embodiments, iron amount may have an upper limit of 0.1 ppm. Depending on the embodiment, and on the water treatment apparatus in question, iron amount may have a higher or a lower upper limit. In some non-limiting embodiments, the upper limit may depend on the type of iron at issue (e.g. elemental, ferric, ferrous). Depending on the embodiment, and on the water treatment apparatus in question, total iron content may not exceed 10 ppm, or it may not exceed 1.5 ppm, or it may not exceed 0.3 ppm, or it may not exceed 0.1 ppm In some non-limiting embodiments, manganese presence may or may not be permitted. Depending on the embodiment, and on the water treatment apparatus in question, manganese may or may not be present, for example, to an upper limit of 0.05 ppm in some embodiments, or 5 ppm in others. In some non-limiting embodiments, lead presence may not be permitted. Depending on the embodiment, and on the water treatment apparatus in question, lead may or may not be present. Lead presence may present an issue to be addressed at the water source rather than at the premises. The numbers provided here are intended to be exemplary and not all-inclusive.

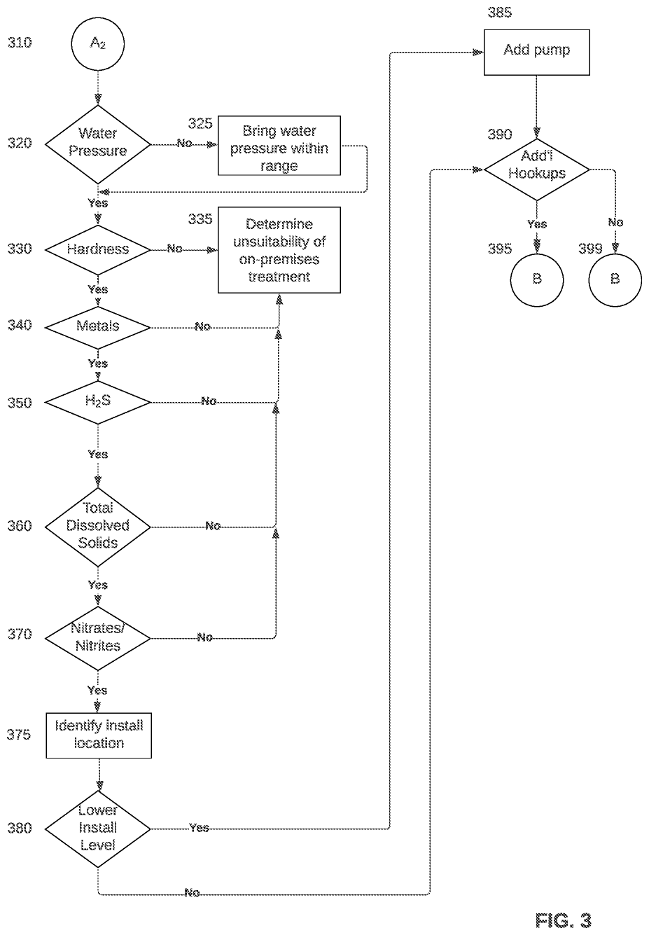

If the metal or metals are present within a range that is acceptable to the apparatus, then at 260 the water's pH is assessed. If the pH is in a range that is acceptable to the apparatus, then at 270 the water source (well or city, or in different embodiments, a different source) is identified. For a well, at 290 flow goes either back to FIG. 1 or to one or more of FIGS. 3, 4A-4C, and 5A-5D (e.g. B may become one or more of A₂, A₃, or A₄). At 280, city water may be tested for chlorine. The chlorine values may pertain to one or more of free chlorine, combined chlorine, or total chlorine. If the chlorine values are within a range that is acceptable to the apparatus, then at 290 flow goes either back to FIG. 1 or to one or more of FIGS. 3, 4A-4C, and 5A-5D (e.g. B may become one or more of A₂, A₃, or A₄). Depending on the embodiment, an acceptable range for total amount of chlorine may be 1 to 10 ppm, or 0.2 to 8 ppm, or simply greater than 0.4 or 1 or 2 ppm, or simply no more than 6 or 5 or 4 ppm. The numbers provided here are intended to be exemplary and not all-inclusive.

It should be noted that, if as a result of any of the assessments at 230-260 or 280 is outside of a range that is acceptable to the apparatus, then flow returns to 235, and a determination is made that that particular on-premises treatment is not available. Recourse could be to a number of resources, from a more specialized testing and treatment service to, in the case of a municipality, a request to the municipality to treat the water supply more generally. In the case of a well or other more local source, an alternative may be to dig another well, or perhaps to treat more generally the groundwater from the well is sourced.

Ordinarily skilled artisans will appreciate that the sequence of assessments shown in FIG. 2 is not critical, and that the assessments may be carried out in any desired order.

In one aspect, FIG. 3 is a flowchart depicting a non-limiting exemplary path to identification of a suitable RO treatment apparatus according to an embodiment. In FIG. 3, at 310 the flow begins. In an embodiment, at 320, water pressure is assessed. Water pressure also is assessed in the flowchart of FIG. 1, as well as in FIG. 2, as just discussed. However, depending on the embodiment, it is possible that water pressure may be in a suitable range for one type of treatment apparatus, but not for another. The water pressure assessment in FIG. 1 is a preliminary determination of whether the pressure is in a range that would be acceptable for at least one type of treatment apparatus. The acceptable water pressure range for RO treatment apparatus may be different from that of UV treatment apparatus.

If the water pressure assessment at 320 is unfavorable, then at 325 a recommendation may be made to bring the water pressure within an acceptable range. Flow then proceeds to 330, at which water hardness may be assessed. If water hardness is within a range that is acceptable for the apparatus, then at 340 an assessment for presence of one or more metals may be carried out. Metals that may be tested for may include, but are not limited to copper lead, iron, and manganese. Ordinarily skilled artisans will appreciate that in different environments, different metals may be present in a water supply, and so may need to be tested for. In an embodiment, manganese or one or more of the other metals may be tested for only in the case of the water source being a well (water source determination occurring in FIG. 1 in an embodiment).

If the metal or metals are present within a range that is acceptable to the apparatus then at 350 an assessment for H₂S may made. In an embodiment, H₂S may be tested for only in the case of the water source being a well. If H₂S is present in a range that is acceptable to the apparatus, then at 360 an assessment for the presence of total dissolved solids (TDS) may be made.

Ordinarily skilled artisans will appreciate that TDS concentration generally may be considered to be the sum of positively charged ions (cations) and negatively charged ions (anions) in the water. These ions may come from a wide range of sources. For example, TDS may include inorganic salts, including but not limited to sodium, potassium, calcium, magnesium, bicarbonates, chlorides, and sulfates, as well as minerals. Small amounts of organic matter that are dissolved in water also may be counted as TDS.

TDS may originate from natural sources, such as such as mineral springs, carbonate deposits, salt deposits, or sea water, but also may come from sewage, stormwater, agricultural runoff, urban run-off (including, for example, salts used for road de-icing), industrial wastewater, chemicals used in the water treatment process, or the plumbing itself (i.e. the piping or hardware used to convey the water). Ordinarily skilled artisans will appreciate that there may be other TDS sources as well, so the foregoing list should be considered to be non-exhaustive.

If TDS are present in a range that is acceptable to the apparatus, then at 370 an assessment for presence of nitrates or nitrites may be made. Depending on the embodiment, an acceptable range of TDS may vary. In different embodiments, TDS may be present in an amount less than or equal to 2500 ppm, 2000 ppm, or 1500 ppm, or 1000 ppm, or 500 ppm, or any value in and among the values just listed.

If nitrates/nitrites are present in a range that is acceptable to the apparatus, then at 375 a location on the premises for installation of the RO apparatus is identified. Depending on the embodiment, an acceptable range of nitrates/nitrites may vary. In different embodiments, nitrates/nitrites may be present in an amount less than or equal to 100 ppm, or 90 ppm, or 80 ppm, or 70 ppm, or 60 ppm, or 50 ppm, or 40 ppm, or 30 ppm, or 20 ppm, or 10 ppm, or any value in and among the values just listed. In some embodiments, the apparatus may be installed in a lower location than the water outlet (e.g. a faucet, a refrigerator) which is receiving output water from the RO apparatus. For example, for reasons of space the RO apparatus may be installed downstairs, e.g. in a basement or ground floor. This location determination is made at 380. If the RO apparatus is at a lower level than the water outlet that is receiving the RO apparatus output, a pump may be required, as for example at 385. At 390, a determination is made whether there are to be additional hookups for the RO apparatus, and whether any of those additional hookups are higher in elevation than the location of the RO apparatus. If so, the pump (if there is one already) may be connected to the additional hookups as well. If there is not a pump already, then one can be included in the recommendation. If there are additional hookups, at 395 one type of recommendation may be made for an RO installation, and flow goes back either to FIG. 1 or to one or more of FIG. 2, 4, or 5A-5D (e.g. B may become one or more of A₁, A₃, or A₄). If there are not additional hookups, at 399 another type of recommendation may be made for an RO installation, and flow goes back either to FIG. 1 or to one or more of FIG. 2, 4, or 5A-5D (e.g. B may become one or more of A₁, A₃, or A₄).

It should be noted that, if as a result of any of the assessments at 330-370 is outside of a range that is acceptable to the apparatus, then flow returns to 335, and a determination is made that that particular on-premises treatment is not available. Recourse could be to a number of resources, from a more specialized testing and treatment service to, in the case of a municipality, a request to the municipality to treat the water supply more generally. In the case of a well or other more local source, an alternative may be to dig another well, or perhaps to treat more generally the groundwater from the well is sourced.

Ordinarily skilled artisans will appreciate that the sequence of assessments shown in FIG. 3 is not critical, and that the assessments may be carried out in any desired order.

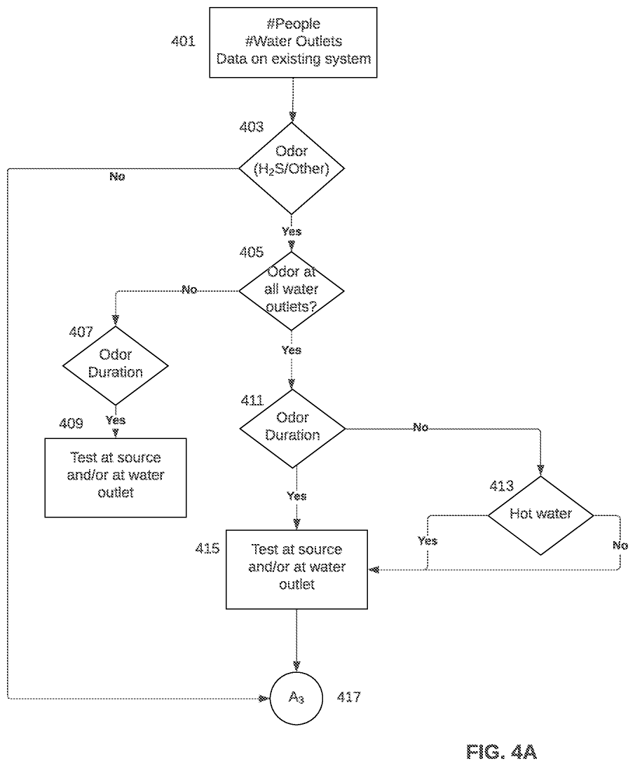

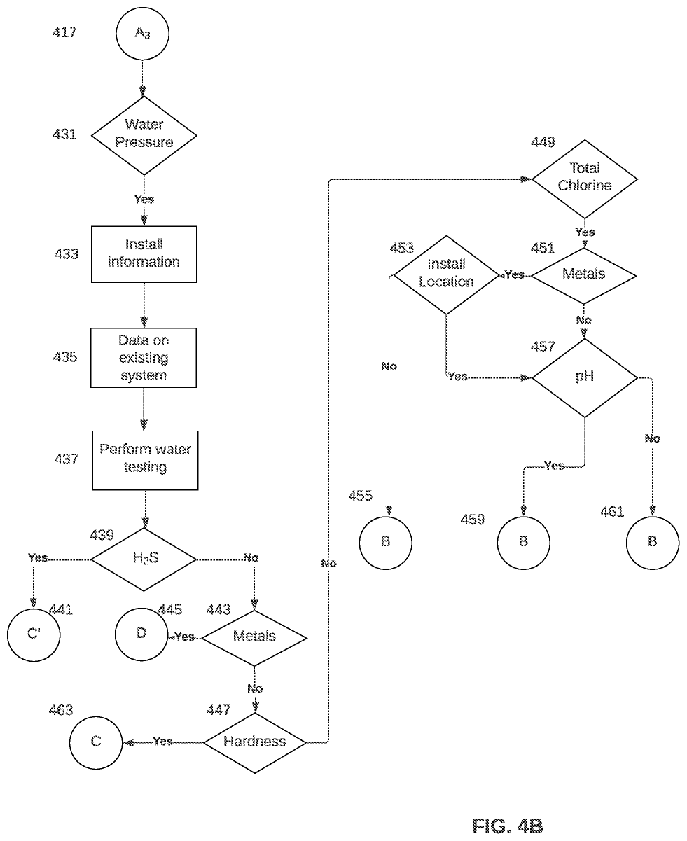

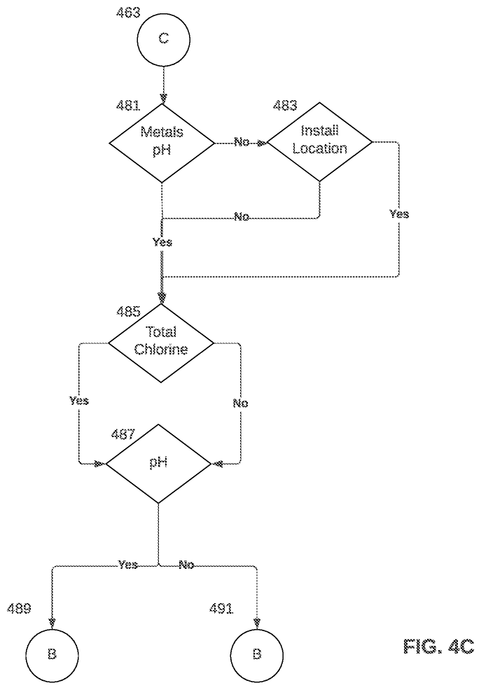

FIG. 4A is a flowchart depicting a portion of a non-limiting exemplary path to identification of a suitable water treatment system according to an embodiment. In FIG. 4A, in an embodiment, as part of a premises evaluation, at 401 there is acquisition of data regarding a number of people and water outlets, as well as data on any existing water treatment system on the premises. In an embodiment, acquired data also may include data on other existing equipment, such as a hot water heater. At 403, a determination of presence of H₂S, and accompanying odor, may be made. If there is no such odor, then flow may proceed to 417, for a more detailed evaluation of point of entry for a water source to the premises.

If there is an odor, or H₂S otherwise is determined to be present, at 405 it is determined whether the odor exists at all of the water outlets. If such is not the case, then at 407 a determination may be made as to the duration of the odor at the water outlets when water is running. If the duration is sufficiently short, that is, if the odor goes away after a predetermined period of time, for example, three to five minutes, a determination may be made that the cause of the odor is somewhere in a section of the plumbing system on the premises. If the odor does not go away in the predetermined period of time, a determination may be made that the cause of the odor may be in a drain, or in a section of the plumbing system. At 409, testing is done at the outlet(s) in question, and/or at the source.

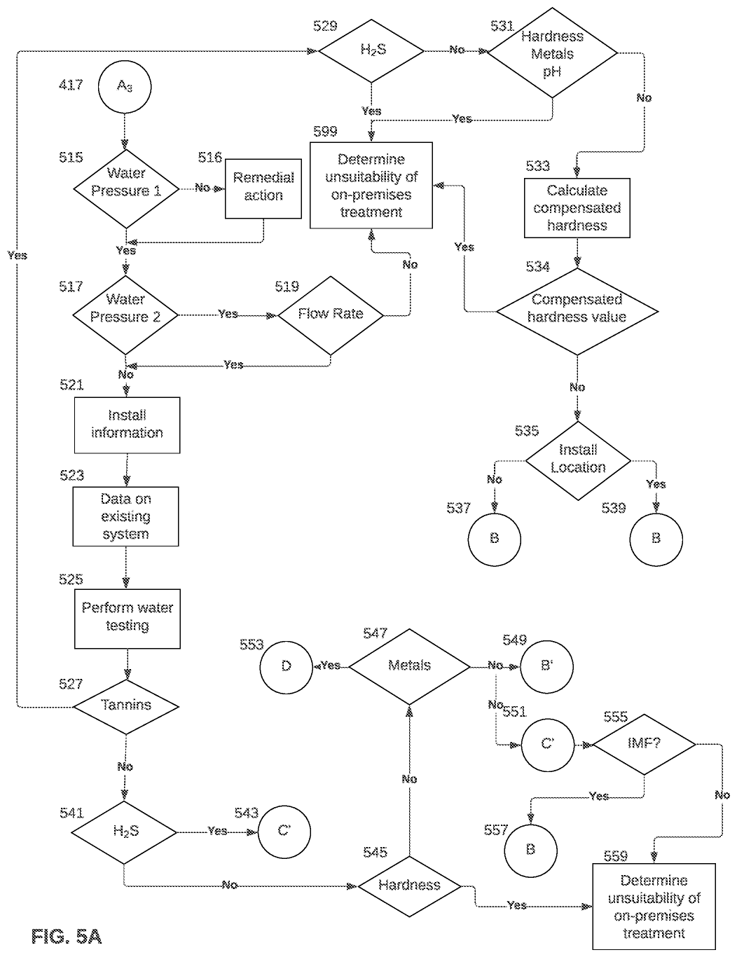

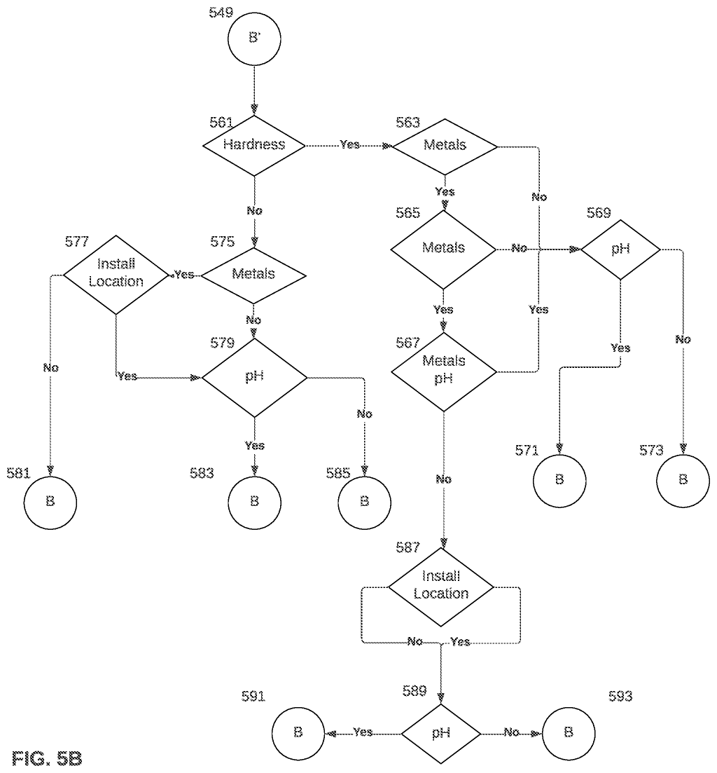

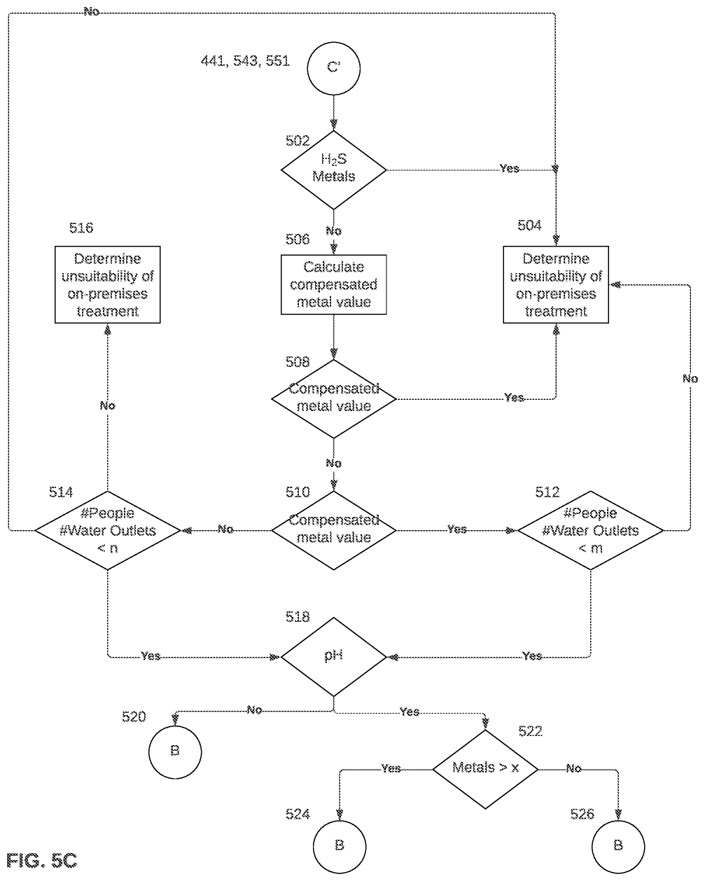

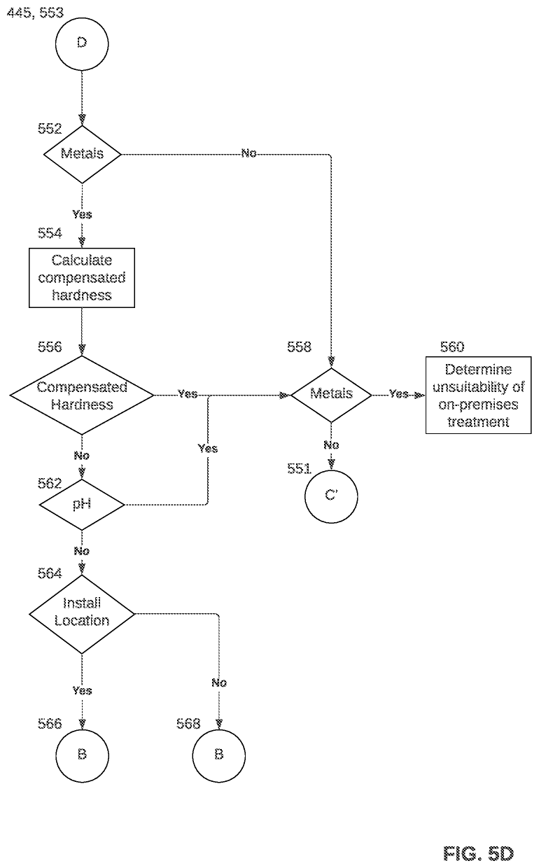

If the odor is present at all of the water outlets, then at 411 a determination may be made as to the duration of the odor at the water outlets at which the odor is present, when water is running through those outlets. If the odor goes away in the predetermined period of time, then a determination may be made that the source of the odor is somewhere in the plumbing system. If the odor does not go away in the predetermined period of time, then at 413 it may be determined whether the odor occurs only when hot water is on. If it does, then a determination may be made that the hot water heater is the source of the odor. If it does not, then a determination may be made that the source of the odor is somewhere else in the system. In either event, at 415 testing may be carried out at the water source and/or at the water outlets to confirm, for example, elevated H₂S levels. Flow then proceeds to 417, and FIG. 4B or FIG. 5B.

Ordinarily skilled artisans will appreciate that the sequence of assessments shown in FIG. 4A is not critical, and that the assessments may be carried out in any desired order. Ordinarily skilled artisans also will appreciate that any redundancies in testing and/or data compilation that are shown in any of the figures can mean that that testing and/or data compilation can be done at various points in the process of devising a suitable water treatment system recommendation. Non-limiting examples of testing may include various types of well water tests, including what ordinarily skilled artisans will understand to be a spin touch well water test; one or more types of manganese test, one or more types of hydrogen sulfide test, one or more types of tannin tests, including a tannin visual test.

FIG. 4B is a flowchart depicting a non-limiting exemplary path to identification of a suitable water treatment according to an embodiment. In an embodiment, FIG. 4B may related to suitable water treatment for a city water source. In FIG. 4B, at 431 the water pressure is checked. If the water pressure is acceptable, then at 433 information about the necessary installation information may be assessed. This information may include, but need not be limited to water pipe diameter, water pipe type, desired water treatment installation location, location of point of entry of the water source to the premises, drain locations, and the like. Ordinarily skilled artisans will appreciate that this list is not exhaustive.

At 435, an assessment of any existing water treatment installation may be made. At 437, water testing may be carried out. At 439, a determination of presence of H₂S (a non-limiting example of odor) may be made. If H₂S is present, then flow goes to 441 (FIG. 5C). If H₂S is not present, then at 443 testing may be carried out for metals. In an embodiment, iron may be one of the metals tested for, but ordinarily skilled artisans will appreciate that other metals may be tested for at this time. If metals are present, then flow goes to 445 (FIG. 5D). If at 443 it is determined that metals are not present, then hardness may be tested at 447. If hardness is above a certain amount (in an embodiment, 3.5 grains per gallon (gpg), then flow goes to 463 (FIG. 4C). If hardness is not above that certain amount, then flow may proceed to 449, at which testing is done for a total amount of chlorine. If total chlorine is above a predetermined amount (in an embodiment, about 0.4 parts per million (ppm), then at 451 further testing is done to determine whether metals, for example iron, are present in less than a predetermined amount (for example, about 0.3 ppm). If total chlorine is not present above the predetermined amount, it may be determined that a point of entry water treatment system is not necessary. However, in an embodiment, flow still can proceed to 451.

At 451, if metals are present in less than a predetermined amount, then at 453 a determination may be made regarding installation location (for example, whether the installation will be in an outdoor or a garage warm climate location). In an embodiment, if the installation will be in an outdoor or a garage warm climate location, then at 455 flow may return to FIG. 1 as indicated, with a recommendation for a water treatment system. In an embodiment, if the installation will not be in an outdoor or a garage warm climate location, then at 457 a determination may be made whether pH is below a predetermined amount (for example, about 6.5). If it is, then at 459 flow may return to FIG. 1, with a different water treatment system recommendation. If the pH is not below the predetermined amount, then at 461 flow may return to FIG. 1 with yet a different water treatment system recommendation. In embodiments, any or all of these recommendations may take into account the number of water outlets and/or the number of people on the premises.

Ordinarily skilled artisans will appreciate that the sequence of assessments shown in FIG. 4B is not critical, and that the assessments may be carried out in any desired order. Ordinarily skilled artisans also will appreciate that any redundancies in testing and/or data compilation that are shown in any of the figures can mean that that testing and/or data compilation can be done at various points in the process of devising a suitable water treatment system recommendation.

FIG. 4C is a flowchart depicting a non-limiting exemplary path to identification of a suitable water conditioning and/or softening treatment according to an embodiment. In FIG. 4C, at 481 metals and pH may be tested for. The metals for which testing may be carried out may include iron and/or copper in an embodiment. Ordinarily skilled artisans will appreciate that testing for other metals may be carried out. In an embodiment, metal testing may be done, for example, to determine whether iron is present in amount greater than about 0.1 ppm, or whether any copper is present at all. Depending on the embodiment, pH may be tested to see whether pH is greater than about 9.0, or 7.0, or 6.5, or 6.4, or 6, or 5, or any value in and among those just listed. Depending on the embodiment, pH may be in a range. Non-limiting examples of ranges are 4 to 9, 5 to 8, 5 to 6.5, 7 to 9, 6.5 to 9, 6.5 to 8, or 6.5 to 7.2.

Ordinarily skilled artisans will appreciate that different pH values and ranges may affect the amounts of various materials that a designed water treatment system may have. For example, the amount of ferrous iron, or ferric iron, or other metal or material that can affect pH, may be limited or increased. Depending on the embodiment, higher pH may limit the amount of one or more of these materials that can be handled, or lower pH may increase the amount of one or more of these materials that can be handled. In specific non-limiting embodiments, pH above 7 or 7.2 may limit the amount of ferrous iron to a maximum of 7 ppm; or a pH somewhere below 7 or 7.2 may permit as much as 10 ppm of ferrous iron.

In an embodiment, if any of these criteria are met, then at 485 a determination of presence of total chlorine above a predetermined amount (for example, more than about 0.4 ppm). If metals and chlorine are not present in any of the indicated amounts, then at 483 a determination may be made whether the installation will be in an outdoor or a garage warm climate location. Depending on the embodiment, this determination may lead to different water treatment system recommendations. In an embodiment, at 485 testing may be done to determine whether chlorine is present above a predetermined amount (for example, about 0.4 ppm). Depending on the embodiment, this determination may lead to different water treatment system recommendations. In an embodiment, at 487 testing may be done to determine whether pH is below a predetermined amount (for example, about 6.5). Depending on the embodiment, this determination may lead to different water treatment system recommendations. At 489 or 491, flow may return to FIG. 1 with one or more water treatment system recommendations, which may depend on the number of water outlets and/or number of people on the premises.

Ordinarily skilled artisans will appreciate that the sequence of assessments shown in FIG. 4C is not critical, and that the assessments may be carried out in any desired order. Ordinarily skilled artisans also will appreciate that any redundancies in testing and/or data compilation that are shown in any of the figures can mean that that testing and/or data compilation can be done at various points in the process of devising a suitable water treatment system recommendation.

FIG. 5A is a flowchart depicting a non-limiting exemplary path to identification of a suitable water treatment system according to an embodiment. In an embodiment, FIG. 5A may be applicable to a water treatment system for a well water source. In FIG. 5A, coming from FIG. 4A, in an embodiment, at 515 and 517 separate water pressure assessments may be made. At 515 a determination may be made whether water pressure is within an acceptable range, for example, between about 30 PSI and about 125 PSI. If it is not, then at 516 some suitable remedial action may be taken to bring the pressure within the acceptable range.

If the water pressure is within the acceptable range, then flow may proceed to 517 for a further water pressure examination, for example, to determine whether top end water pressure is within a predetermined range, for example, between 30 and 35 PSI. If it is, then a determination may be made whether a flow rate of a well pump is above a predetermined level. If it is not, then flow goes to 599, and a determination is made that a suitable water treatment system cannot be installed.

Depending on the embodiment, a minimum flow rate may be at least 5 gpm, or 8 gpm, or 15 gpm, or no more than 8 gpm or 15 gpm, or any value within the just specified amounts. In an embodiment, flow rate may affect the performance of a UV system that might be installed in a premises.

At 517, if the top end water pressure is not within the predetermined range, then at 521 information about installation (e.g. pipe diameter and/or type, location of water source point of entry, power and drain location, and/or desired installation location) maybe compiled. At 523, data on any existing water treatment system may be gathered. At 525, water system testing may be performed.

In an embodiment, at 527, a determination may be made whether tannins are present in the water. If they are, then at 529 testing is done to determine presence of H₂S. If H₂S is present, then flow may proceed to 599 for a determination of unsuitability of on-premises treatment. If H₂S is not present, then at 531 measurements may be taken of hardness, pH, and/or presence of metals. In an embodiment, the metals may include manganese, iron, ferrous iron, and/or ferric iron. If any of these hardness or pH values, or presence of metal amounts, is above a predetermined amount, then flow may proceed to 599 for a determination of unsuitability of on-premises treatment. If these values and/or amounts are not above the predetermined amounts, then at 533 a calculation may be made regarding a value which ordinarily skilled artisans may recognize as a compensated hardness. Depending on the embodiment, this value is a combination of hardness and metal presence. In an embodiment, the metal may be iron and/or manganese. In an embodiment, compensated hardness may be calculated as a weighted average of hardness value and metal presence.

At 534, a determination may be made whether the compensated hardness value is above a predetermined value. If it is, then flow may proceed to 599 for a determination of unsuitability of on-premises treatment. If It is not, then at 535 there may be an examination of whether the installation will be outdoors or in a warm climate garage. Depending on the outcome of the examination, flow may return to FIG. 1 with different recommendations, at 537 and 539, respectively.

Returning to 527, if tannins are not present, then at 541 testing may be done to determine whether H₂S is present. If it is, then at 543 flow proceeds to FIG. 5C. If H₂S is not present, then at 545 a determination may be made whether water hardness is above a predetermined amount. If it is, flow may go to 559 for a determination of unsuitability of on-premises treatment. If water hardness is not above a predetermined amount, then at 547 testing may be done for presence of metals such as iron and manganese. In an embodiment, if either or both of these is present above a predetermined amount, then at 553 flow proceeds to FIG. 5D. In an embodiment, if neither of these is present above a predetermined amount, then at 549 flow may proceed to FIG. 5B. Flow also may proceed to FIG. 5C, whereupon if the outcome of FIG. 5C is favorable, then flow may return to FIG. 1 with a solution determined in FIG. 5C. If the outcome of FIG. 5C is not favorable, then flow may go to 559 for a determination of unsuitability of on-premises treatment.

Ordinarily skilled artisans will appreciate that the sequence of assessments shown in FIG. 5A is not critical, and that the assessments may be carried out in any desired order. Ordinarily skilled artisans also will appreciate that any redundancies in testing and/or data compilation that are shown in any of the figures can mean that that testing and/or data compilation can be done at various points in the process of devising a suitable water treatment system recommendation.

FIG. 5B is a flowchart depicting a non-limiting exemplary path to identification of a suitable water conditioning and/or softening system according to an embodiment. In FIG. 5B, flow picks up from 549 in FIG. 5A. At 561, a hardness determination may be made. If water is above a predetermined hardness (in an embodiment, more than about 3.5 gpg), then at 563 and 565 separate testing for metals maybe carried out. In an embodiment, 563 may be a test for iron, and in an embodiment 565 may be a test for manganese. Depending on an embodiment, it may have been determined beforehand whether there will be treatment for either iron or manganese. If there will be such testing, then at 567 further examination may be done on pH and/or a metal such as copper. In an embodiment, if copper and/or pH is above a predetermined amount (e.g. if any copper is present at all and/or pH is above about 9.0), then at 569 a determination may be made whether water will be treated for pH at the source. If so, then at 571 flow may return to FIG. 1 with a water conditioning and/or softening recommendation. If pH treatment will not be done at the source, then at 573 flow may return to FIG. 1 with a different water conditioning and/or softening recommendation.

In an embodiment, at 567 if copper and/or pH is not above the predetermined amount, then at 587 there may be an examination of whether the installation will be outdoors or in a warm climate garage. In either case, at 589 a determination may be made whether to do further pH testing. Depending on the determination, different treatment recommendations may be provided at 591 and 593, respectively.

Returning to 561, if water is not above the predetermined hardness, then at 575 a determination may be made whether one or more metals (in an embodiment, iron) is present in less than a predetermined amount (in an embodiment, less than about 0.3 ppm). If metal is present in less than a predetermined amount, then at 577 there may be an examination of whether the installation will be outdoors or in a warm climate garage. If the installation will not be outdoors or in a warm climate garage, then at 581 flow may return to FIG. 1 with a water conditioning and/or treatment recommendation. If the installation will be outdoors or in a warm climate garage, and/or metals from 575 are not present in less than a predetermined amount, then at 579 a determination may be made whether pH will be tested at the source, or whether pH is greater than a predetermined amount. Depending on the answer, at either 583 or 585 flow may return to FIG. 1 with different water conditioning and/or treatment recommendations.

Ordinarily skilled artisans will appreciate that the sequence of assessments shown in FIG. 5B is not critical, and that the assessments may be carried out in any desired order. Ordinarily skilled artisans also will appreciate that any redundancies in testing and/or data compilation that are shown in any of the figures can mean that that testing and/or data compilation can be done at various points in the process of devising a suitable water treatment system recommendation.

FIG. 5C is a flowchart depicting a non-limiting exemplary path to identification of a suitable water treatment system according to an embodiment. In FIG. 5C, flow begins from FIG. 4B or 5A. At 502 an evaluation is made whether H₂S is present above a predetermined value, or one or more metals are present above a predetermined amount. Depending on the embodiment, the metals may be iron, copper, and/or manganese. If H₂S is present above the predetermined value, or the one or more metals are present above the predetermined amount, then flow proceeds to 504 for a determination of unsuitability of on-premises treatment. If H₂S is not present above the predetermined value, or the one or more metals are present above the predetermined amount, then flow proceeds to 506 for a calculation of a compensated metal value, which may include presence of metals, presence of H₂S, or presence of both. The compensated metal value may be a weighted average of one or more metals and/or H₂S. Depending on the embodiment, the metal may be iron, or manganese, or copper, or a combination of the three. In an embodiment, the weight assigned to H₂S may be between 1 and 10. In an embodiment, the manganese weight may be between 1 and 5. In an embodiment, the weight assigned to iron may be between 1 and 5. In an embodiment, the weight assigned to copper may be between 0 and 3. At 508, a determination is made whether the compensated metal value is above a first predetermined amount. Depending on the embodiment, the first predetermined amount may be 30 ppm, or 15 ppm, or more or less than either of these values.

If the compensated metal value is above a predetermined amount, then flow proceeds to 504 for a determination of unsuitability of on-premises treatment. If it is not, then flow proceeds to 510 for a determination of whether the compensated metal value is above a second, lower predetermined amount. Depending on the embodiment, the second predetermined amount may be 30 ppm, or 15 ppm, or more or less than either of these values. If it is, then at 512 a determination is made regarding whether a number of people and/or water outlets in the premises to be treated is less than a first predetermined number. Depending on the embodiment, the first predetermined number may be 30, or 20, or 15, or 10, or more or less than any of these values. If the number is not less than the first predetermined number, then flow proceeds to 504 for a determination of unsuitability of on-premises treatment. If the number is less than the first predetermined number, then flow proceeds to 518 for a determination of pH.

Returning to 510, if the compensated metal value is not above the second, lower predetermined amount, then flow process to 514 for a determination regarding whether a number of people and/or water outlets in the premises to be treated is less than a second predetermined number. Depending on the embodiment, the first predetermined number may be 30, or 20, or 15, or 10, or more or less than any of these values. If the number is not less than the second predetermined number, then flow proceeds to 504 for a determination of unsuitability of on-premises treatment. If the number is less than the second predetermined number, then flow proceeds to 518 for a determination of pH.

At 518, a determination is made whether pH is less than a predetermined amount. If it is, then at 522 a determination is made whether one or more metals is present in an amount greater than a predetermined amount. If it is, then depending on the route to 518 (from 512 or 514), at 524 different respective recommendations may be made, and flow returns to FIG. 1. If it is not, then depending on the route to 518 (from 512 or 514), at 526 different respective water treatment system recommendations may be made, and flow returns to FIG. 1.

Returning to 518, if the pH is not less than the predetermined amount, then at 520 a different water treatment system recommendation may be made, and flow returns to FIG. 1.

Ordinarily skilled artisans will appreciate that the sequence of assessments shown in FIG. 5C is not critical, and that the assessments may be carried out in any desired order. Ordinarily skilled artisans also will appreciate that any redundancies in testing and/or data compilation that are shown in any of the figures can mean that that testing and/or data compilation can be done at various points in the process of devising a suitable water treatment system recommendation.

FIG. 5D is a flowchart depicting a non-limiting exemplary path to identification of a suitable water treatment system according to an embodiment. In FIG. 5D, flow begins from FIG. 4B or 5A. In an embodiment, at 552 a determination is made whether one or more metals are present in more than respective predetermined amounts. In some embodiments an accompanying evaluation of whether pH is above a predetermined amount may be made. Depending on the embodiment, the one or more metals may be manganese, ferrous iron, and/or ferric iron. If the one or more metals are present in more than respective predetermined amounts (in some embodiments, with pH also being above a predetermined amount), then at 554 a compensated hardness value may be calculated. In an embodiment, the compensated hardness value may be a weighted average of calculated hardness and one or more metal values. In an embodiment, the metals may be iron and/or manganese. Depending on the embodiment, calculated hardness may have a weight between 0 and 1. Depending on the embodiment, calculated metal amounts may have a weight between 1 and 20. Depending on the embodiment, calculated metal amounts may include any or all of iron, copper, and manganese. Depending on the embodiment, a largest weight may be provided to manganese, followed by the weight for iron, followed by the weight for hardness. Depending on the embodiment, compensated hardness may not exceed 75 gpg. Depending on the embodiment, compensated hardness may not exceed 60 gpg. Depending on the embodiment, compensated hardness may not exceed 59 gpg.

At 556, if the compensated hardness value is above a predetermined amount, then flow proceeds to 558, where a further determination is made whether one or more metals may be present in greater than other predetermined amounts. In an embodiment, the metals may be manganese and/or iron. If either is present in an amount above its respective predetermined amount, then flow proceeds to 560 for a determination of unsuitability of on-premises treatment. If neither is present in an amount above its respective predetermined amount, then flow returns to 551 in FIG. 5C.

At 556, if the compensated hardness value is not above a predetermined amount, then flow proceeds to 562, where in an embodiment, a determination is made whether pH is below a predetermined amount. If it is, then flow proceeds to 558, where a further determination is made whether one or more metals may be present in greater than other predetermined amounts. In an embodiment, the metals may be manganese and/or iron. If either is present in an amount above its respective predetermined amount, then flow proceeds to 560 for a determination of unsuitability of on-premises treatment. If neither is present in an amount above its respective predetermined amount, then flow returns to 551 in FIG. 5C.

At 562, if it is determined that the pH is not below the predetermined amount, then flow proceeds to 564, for a determination whether the installation will be outdoors or in a warm climate garage. Depending on the outcome at 564, different respective water treatment system recommendations may be provided at 566 and 568, respectively, and flow returns to FIG. 1.

If the one or more metals are not present in more than the respective predetermined amounts (in some embodiments, with pH also being above the predetermined amount), then at 558 a further determination is made whether one or more metals may be present in greater than other predetermined amounts. In an embodiment, the metals may be manganese and/or iron. If either is present in an amount above its respective predetermined amount, then flow proceeds to 560 for a determination of unsuitability of on-premises treatment. If neither is present in an amount above its respective predetermined amount, then flow returns to 551 in FIG. 5C.

Ordinarily skilled artisans will appreciate that the sequence of assessments shown in FIG. 5D is not critical, and that the assessments may be carried out in any desired order. Ordinarily skilled artisans also will appreciate that any redundancies in testing and/or data compilation that are shown in any of the figures can mean that that testing and/or data compilation can be done at various points in the process of devising a suitable water treatment system recommendation.

In the foregoing flowcharts of FIGS. 1-3, 4A-4C, and 5A-5D, in many instances the depicted sequence of events is not critical. Ordinarily skilled artisans will appreciate that different sequences are possible. By way of non-limiting example, determination of contaminants, whether metals, rust, sediment, chemicals, or other contaminants, need not proceed in a particular order. Water testing may be carried out in any number of ways, looking at presence or absence of particular contaminants in any desired order.

Ordinarily skilled artisans will appreciate that the various ranges and values discussed above for the numerous attributes are not exhaustive of the ranges and values that may be applicable for various types of water treatment apparatus, or of suitability for or applicability to particular applications. Ordinarily skilled artisans also will appreciate that the foregoing listing and discussion of types of water conditioning apparatus, and particular types of treatment apparatus such as UV and RO apparatus, are not exhaustive of the types of systems or solutions that can be applicable for treating City or Well Water with these various water treatment apparatus, including RO and UV systems.

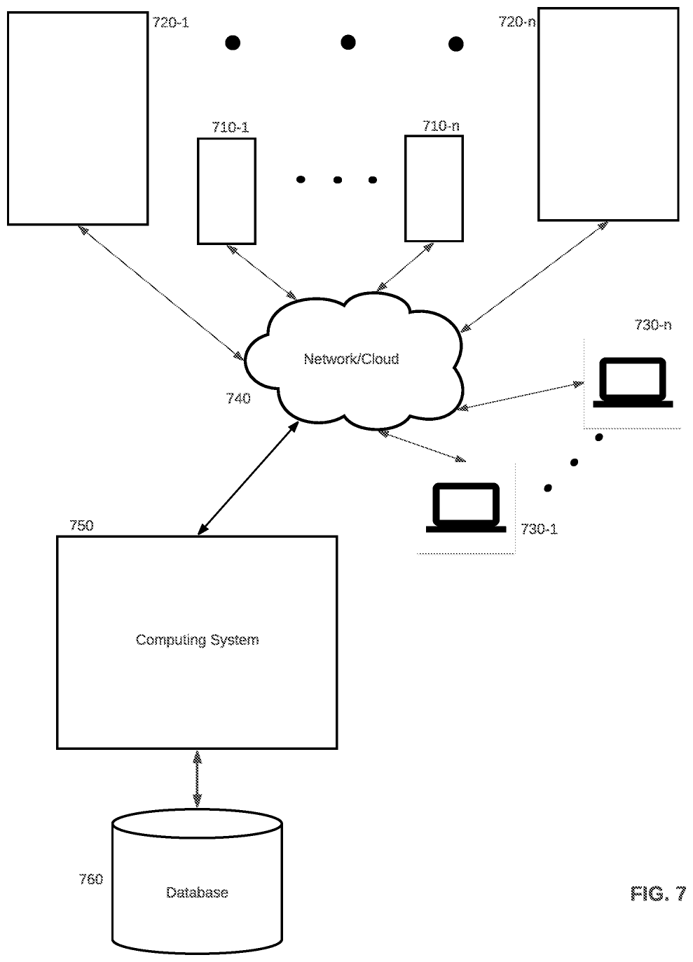

From the foregoing, ordinarily skilled artisans will appreciate that FIGS. 1-3, 4A-4C, and 5A-D exemplify the almost limitless number of combinations of criteria, from pH to presence of different metals to H₂S presence to odor presence to chlorine presence to water source to hardness to bacteria to water pressure to tannins to water flow rate to number of users to other criteria mentioned above but not specifically listed here (in no particular order) that must be taken into consideration in order to devise an appropriate water treatment system recommendation. The sheer number of possible combinations, not only for a particular apparatus or system recommendation, but also for a determination that available apparatus is not suitable, is next to impossible even for a very experienced field engineer and/or sales representative, much less a new field engineer and/or sales representative, to manage. Consequently, a computer system, various embodiments of which will be discussed relative to FIG. 7, is indispensable to the performance of duties, and the recommendations for suitable water treatment equipment and/or systems.

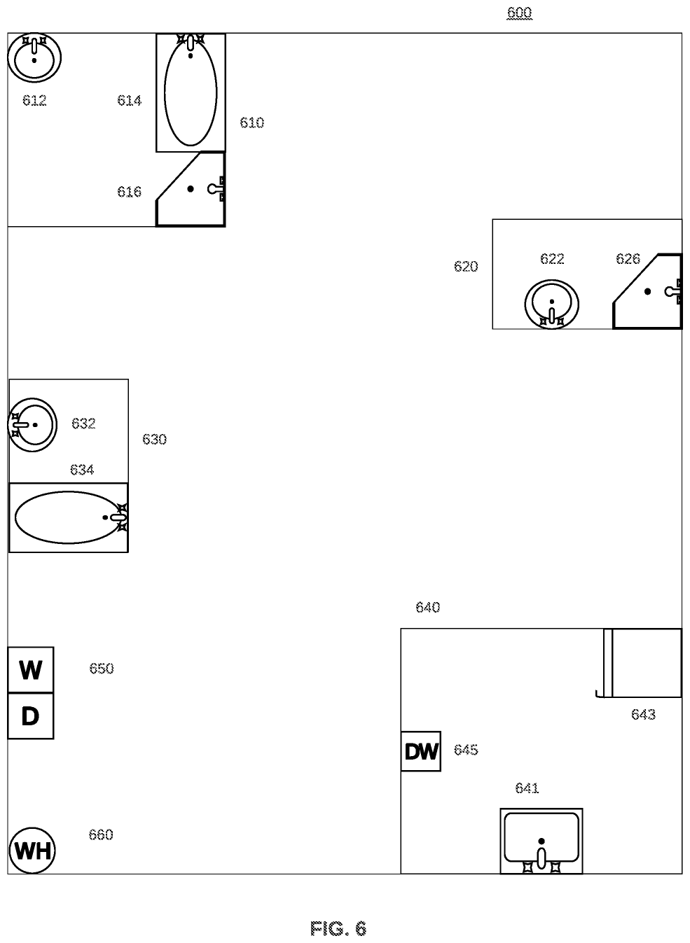

FIG. 6 shows a non-limiting exemplary layout of relevant portions of a premises 600 according to an embodiment. This particular exemplary layout could be of a residence, or, in some instances, of an apartment in an apartment building. The appliances and fixtures in FIG. 6 are non-limiting examples of applications of various water treatment apparatus. In FIG. 6, a first bathroom 610 has a sink 612, a bathtub and/or hot tub 614, and a shower 616. A second bathroom 620 has a sink 622 and a shower 626. A third bathroom 630 has a sink 632 and a bathtub and/or hot tub 634. In kitchen 640, sink 641 may include a faucet to dispense drinking water, as well as a tap to run hot and/or cold water. A refrigerator 643 may contain an icemaker and/or a water dispenser. Premises 600 also has a washing machine 650 and a water heater 660. Depending on the premises, for example, in an apartment building or an office building, there may not be a separate water heater for each apartment or office or office suite. In an office building, there may be sinks, and perhaps a kitchen in various office suites, but not individual bathing facilities such as a shower, bathtub, or hot tub. Depending on the water treatment apparatus being considered, some of the fixtures and/or appliances listed above may or may not be suitable candidates for application of particular water treatment apparatus as part of an overall water treatment solution.

FIG. 7 shows a non-limiting example of a processing system in which embodiments of the present invention may be used. Portable devices 710-1, . . . , 710-n (for example, smartphones or small tablets), 720-1, . . . 720-n (for example, larger tablets), and 730-1, . . . , 730-n (for example, laptop or notebook computers) are connected to a computing system 750 via a network or cloud 740. The computing system 750 has one or more processors (central processing units (CPU), graphics processing units (GPU), or both), one or more volatile memories, one or more non-volatile memories, and non-volatile storage.

In an embodiment, the portable devices run an app into which a user inputs information to be provided to the computing system 750. The information may relate to such things as water source, number of residents, number of water outlets, and the like. In an embodiment, the user may input results of water testing into the app for transmission to the computing system 750. In an embodiment, the water testing equipment may connect directly to the portable devices to provide the test results, avoiding possible user input error.

In an embodiment, computing system 750 connects to a database 760 which may contain any or all of customer records; records of different residences, apartment buildings, and/or office buildings; and information about various products that may form part of a recommended water treatment system. In an embodiment, information about previously developed water treatment systems may be stored for ease of reference in comparable circumstances, which may arise through the data that the app communicates with the computing system 750.

In an embodiment, as necessary the app running on one of the portable devices may receive data from database 760 via computing system 750 to provide water treatment system recommendations to customers. In an embodiment, users may access the computing system 750 to download data to their portable devices, and provide water treatment system recommendations based on the downloaded data on the portable devices. Water testing data can be input to the portable devices, which themselves can process the data to yield the water treatment system recommendations

One advantage of the present invention is that it enables field engineers and/or sales representatives of all levels of experience or familiarity with a company's water treatment products to provide informed recommendations to customers. The engineers and representatives can hold the necessary analysis device in their hands, either as a stand-alone, or as a portable device communicating with a central location that performs the analysis and provides the results to the portable device.

While numerous embodiments in accordance with different aspects of the invention have been described in detail, various modifications within the scope and spirit of the invention will be apparent to ordinarily skilled artisans. In particular, certain methods are disclosed, as well as individual steps for performing those methods. It should be understood that the invention is not limited to any particular disclosed sequence of method steps. Consequently, the invention is to be construed as limited only by the scope of the following claims.

What is claimed is:

1. A computer-implemented method of designing a water treatment system at a premises, the method comprising:
using a computer, inputting the following data:
water usage, comprising a number of water outlets and a number of users on the premises;
water source;
water pressure;
water pH;
water hardness;
water odor;
metal content in the water, wherein the metal is selected from the group consisting of iron, ferrous iron, ferric iron, copper, manganese;
responsive to a determination that the water source is municipal, chlorine content;
using a computer, responsive to a determination that one or more of water usage, water source, water pressure, water pH, water hardness, water odor, metal content, and chlorine content are within respective predetermined ranges, generating a water treatment recommendation responsive to the input data; and
responsive to the generated water treatment recommendation, designing the water treatment system.

2. The method of claim 1, wherein using the computer comprises using a handheld device that communicates with a central computing system to transmit the data and receive the water treatment recommendation.

3. The method of claim 1, wherein using the computer comprises using a handheld device to input data and generate the water treatment recommendation.

4. The method of claim 2, wherein the handheld device generates a design for the water treatment system responsive to the generated water treatment recommendation.

5. The method of claim 1, further comprising installing the designed water treatment system.

6. The method of claim 2, further comprising installing the designed water treatment system.

7. The method of claim 3, further comprising installing the designed water treatment system.

8. The method of claim 4, further comprising installing the designed water treatment system.

9. The method of claim 1, wherein the premises are selected from the group consisting of detached houses, townhouses, duplexes, condominiums, coops, apartment buildings, and office buildings.

10. The method of claim 1, further comprising, responsive to the amount of metal present in the water, calculating a compensated hardness value that is a weighted average of at least two values selected from the group consisting of hardness, iron content, and manganese content and generating the water treatment recommendation responsive to a determination that the compensated hardness value is within a predetermined compensated hardness range.

11. The method of claim 1, further comprising, responsive to the amount of metal present in the water, calculating a compensated metal value that is a weighted average of at least two values selected from the group consisting of pH, iron content, manganese content, and copper content, and generating the water treatment recommendation responsive to a determination that the compensated hardness value is within a predetermined compensated hardness range.

12. The method of claim 11, wherein the iron content may comprise one or more of elemental iron, ferric iron, or ferrous iron.

13. The method of claim 1, further comprising, responsive to a determination that one or more of water usage, water source, water pressure, water pH, water hardness, metal content, chlorine content, and water odor are outside of respective predetermined ranges, altering the water treatment recommendation.

14. The method of claim 13, wherein responsive to a determination that the water pressure is outside of a predetermined water pressure range, including, as part of the water treatment recommendation, that additional equipment be added to bring the water pressure within the predetermined water pressure range.

15. The method of claim 1, further comprising, responsive to a determination that the metal content is outside of a predetermined metal content range, including, as part of the water treatment recommendation, that water be treated at the water source to remediate the amount of metal content.

16. The method of claim 1, further comprising, responsive to a determination that the chlorine content is outside of a predetermined chlorine content range, including, as part of the water treatment recommendation, that water be treated at the water source to remediate the amount of chlorine content.

17. The method of claim 9, further comprising, responsive to a determination that water odor is outside of a predetermined water odor range, determining whether the water odor is present at all of the water outlets.

18. The method of claim 17, further comprising, responsive to determining whether the water odor is not present at all of the water outlets, identifying one or more of portions of on-premises piping and water heating apparatus as a source of the water odor.

19. The method of claim 5, further comprising, responsive to installing the water treatment system, configuring the water treatment system to satisfy electrical and mechanical requirements for the installed water treatment system.

20. The method of claim 19, wherein configuring the water treatment system comprises programming valve head controls in the installed water treatment system, further comprising providing valve setting instructions, including instructions selected from the group consisting of regeneration cycle timing, brine draw timing, backwash timing, and rinse and refill timing.
